(19) United States
(12) Patent Application Publication
(10) Pub. No.: US 2023/0136067 A1
(43) Pub. Date: May 4, 2023

(54) DISPLAY DEVICE

(71) Applicant: Samsung Display Co., LTD., Yong-si (KR)

(72) Inventors: CHAUNGI CHOI, Suwon-si (KR); HYOENG-KI KIM, Suwon-si (KR); HOONGI LEE, Suwon-si (KR)

(21) Appl. No.: 17/976,497

(22) Filed: Oct. 28, 2022

(30) Foreign Application Priority Data
Nov. 2, 2021 (KR) 10-2021-0149200

(51) Int. Cl. H01L 27/32; H01L 51/56

(52) U.S. Cl. CPC H01L 27/3276; H01L 51/56; H01L 51/0097

(57) ABSTRACT

A display device includes: a display panel having a first non-folding portion, a first folding portion, a second non-folding portion, a second folding portion, and a third non-folding portion arranged along a first direction, wherein each of the first to third non-folding portions has a display area, a bending area extending along a second direction crossing the first direction, and a pad area connected to the display area with the bending area interposed therebetween; a first data driving chip on a first pad area of the first non-folding portion; a second data driving chip on a second pad area of the second non-folding portion; a third data driving chip on a third pad area of the third non-folding portion; and a circuit board attached on any one of the first to third pad areas and electrically connected to the first to third data driving chips.

### CROSS-REFERENCE TO RELATED APPLICATION

The present application claims priority to and the benefit of Korean Patent Application No. 10-2021-0149200, filed on Nov. 2, 2021, the entirety of which is incorporated herein by reference.

### BACKGROUND

### 1. Field

Aspects of some embodiments of the present disclosure relate to a display device.

### 2. Description of the Related Art

Flat panel display devices are replacing cathode ray tube display devices as display devices due to their relative lightweight and thin characteristics. Flat panel display devices may include, for example, liquid crystal display devices and organic light emitting diode display devices.

Additionally, flat panel display devices may include foldable display devices that are configured to be folded while being carried or stored and unfolded while displaying images. Foldable display devices may be relatively easy to carry and can implement a large screen. When foldable display devices include a plurality of folding portions, the screen may be larger.

The above information disclosed in this Background section is only for enhancement of understanding of the background and therefore the information discussed in this Background section does not necessarily constitute prior art.

### SUMMARY

Aspects of some embodiments of the present disclosure relate to a display device. For example, embodiments of the present disclosure relate to a foldable display device including a plurality of folding portions.

Aspects of some embodiments of the present disclosure provide a display device having a high resolution and driven at a high speed.

Aspects of some embodiments of the present disclosure also include a display device with relatively improved reliability.

Additional characteristics of some embodiments of the present disclosure will be set forth in the description which follows, and in part will be apparent from the description, or may be learned by practice of the disclosures.

According to some embodiments, a display device includes: a display panel, a first data driving chip, a second data driving chip, a third data driving chip, and a circuit board. The display panel may have a first non-folding portion, a first folding portion, a second non-folding portion, a second folding portion, and a third non-folding portion arranged in a first direction. Each of the first to third non-folding portions may have a display area, a bending area positioned in a second direction crossing the first direction from the display area, and a pad area connected to the display area with the bending area interposed therebetween. The first data driving chip may be located on a first pad area of the first non-folding portion. The second data driving chip may be located on a second pad area of the second non-folding portion. The third data driving chip may be located on a third pad area of the third non-folding portion. The circuit board may be attached on any one of the first to third pad areas and electrically connected to the first to third data driving chips.

According to some embodiments, the first folding portion may be folded about a first folding axis extending in the second direction. The second folding portion may be folded about a second folding axis spaced apart from the first folding axis in the first direction and extending in the second direction.

According to some embodiments, a first notch overlapping the first folding axis and concave inward may be formed between the first pad area and the second pad area of the display panel. A second notch overlapping the second folding axis and concave inward may be formed between the second pad area and the third pad area of the display panel.

According to some embodiments, in each of the first to third non-folding portions, the bending area may be bent about a bending axis extending in the first direction such that the pad area is positioned under the display area. Each of the first notch and the second notch may overlap the bending axis.

According to some embodiments, the circuit board may be attached on the second pad area of the second non-folding portion to be spaced apart from the second data driving chip.

According to some embodiments, the display panel may include a first data connection line including a first end portion positioned in the first pad area and a second end portion positioned in the second pad area. The first data connection line may electrically connect the first data driving chip and the circuit board.

According to some embodiments, the first data connection line may overlap the first non-folding portion, the first folding portion, and the second non-folding portion.

According to some embodiments, the first data connection line may extend to surround the first notch.

According to some embodiments, the display panel may further include a first resin layer, a first barrier layer on the first resin layer, a second resin layer on the first barrier layer, a second barrier layer on the second resin layer, a buffer layer on the second barrier layer, a thin film transistor on the buffer layer, and a light emitting element electrically connected to the thin film transistor.

According to some embodiments, the first barrier layer may include a first lower barrier layer on the first resin layer and a first upper barrier layer between the first lower barrier layer and the second resin layer. The first data connection line may be between the first lower barrier layer and the first upper barrier layer.

According to some embodiments, the second barrier layer may include a second lower barrier layer on the second resin layer and a second upper barrier layer between the second lower barrier layer and the buffer layer. The first data connection line may be between the second lower barrier layer and the second upper barrier layer.

According to some embodiments, the first data connection line may be between the second barrier layer and the buffer layer.

According to some embodiments, the display panel may further include a second data connection line including a first end portion positioned in the third pad area and a second end portion positioned in the second pad area. The second data connection line may electrically connect the third data driving chip and the circuit board.

According to some embodiments, the second data connection line may extend to surround the second notch.

According to some embodiments, the display panel may further include a data transmission line positioned in the second pad area and electrically connecting the second data driving chip and the circuit board. The data transmission line may be on a different layer from the first data connection line.

According to some embodiments, the display device may further include a gate driver on the first non-folding portion. The display panel may further include a gate connection line including a first end portion positioned in the first pad area and a second end portion positioned in the second pad area. The gate connection line may electrically connect the gate driver and the circuit board.

According to some embodiments, the gate connection line may be on the same layer as the first data connection line.

According to some embodiments, the display panel may further include a driving voltage line and a power connection line. The driving voltage line may extend in the first direction, and may partially overlap the first non-folding portion. The power connection line may include a first end portion positioned in the first pad area and a second end portion positioned in the second pad area. The power connection line may electrically connect the driving voltage line and the circuit board.

According to some embodiments, the power connection line may be on the same layer as the first data connection line.

A display device according to some embodiments may include a display panel, a first data driving chip, a second data driving chip, a third data driving chip, and a circuit board. The display panel may have a first non-folding portion, a first folding portion, a second non-folding portion, a second folding portion, and a third non-folding portion arranged in a first direction. Each of the first to third non-folding portions may have a display area, a bending area positioned in a second direction crossing the first direction from the display area, and a pad area connected to the display area with the bending area interposed therebetween. The first data driving chip may be on a first pad area of the first non-folding portion. The second data driving chip may be on a second pad area of the second non-folding portion. The third data driving chip may be on a third pad area of the third non-folding portion. The circuit board may be attached on the second pad area of the second non-folding portion to be spaced apart from the second data driving chip, and may be electrically connected to the first to third data driving chips. The display panel may include a first data connection line and a second data connection line. The first data connection line may include a first end portion positioned in the first pad area and a second end portion positioned in the second pad area, and may electrically connect the first data driving chip and the circuit board. The second data connection line may include a first end portion positioned in the third pad area and a second end portion positioned in the second pad area, and may electrically connect the third data driving chip and the circuit board.

According to some embodiments, the display device may include the display panel and the plurality of data driving chips. The display panel may include the plurality of non-folding portions and the plurality of folding portions arranged in the first direction. Each of the folding portions may be positioned between two adjacent non-folding portions. The data driving chips may be respectively mounted at end portions of the non-folding portions in the second direction crossing the first direction. Accordingly, the display device may have a high resolution and may be driven at a relatively high speed.

According to some embodiments, the circuit board electrically connected to the data driving chips may be attached on any one of the non-folding portions. The circuit board may be electrically connected to the data driving chips in the non-folding portions to which the circuit board is not attached through the connection lines included in the display panel. Accordingly, a reliability of the display device may be relatively improved even when the display device is folded.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the disclosures.

FIG. 1 is a block diagram illustrating a display device according to some embodiments.

FIG. 2 is a plan view illustrating a display device according to some embodiments.

FIG. 3 is a plan view schematically illustrating connection lines included in the display device of FIG. 2.

FIG. 4 is a cross-sectional view taken along the line I-I′ of FIG. 2.

FIG. 5 is an enlarged plan view of area ‘A’ of a display panel included in the display device of FIG. 2 according to some embodiments.

FIG. 6 is a cross-sectional view taken along the line II-II′ of FIG. 5.

FIG. 7 is a cross-sectional view taken along the line III-Ill′ of FIG. 5.

FIG. 8 is a cross-sectional view taken along the line IV-IV′ of FIG. 5.

FIGS. 9 to 15 are views illustrating a method of manufacturing a display device according to some embodiments.

FIGS. 16 and 17 are cross-sectional views illustrating a display device according to some embodiments.

FIGS. 18 and 19 are cross-sectional views illustrating a display device according to some embodiments.

FIG. 20 is a block diagram illustrating an electronic device according to some embodiments.

### DETAILED DESCRIPTION

Illustrative, non-limiting embodiments will be more clearly understood from the following detailed description in conjunction with the accompanying drawings.

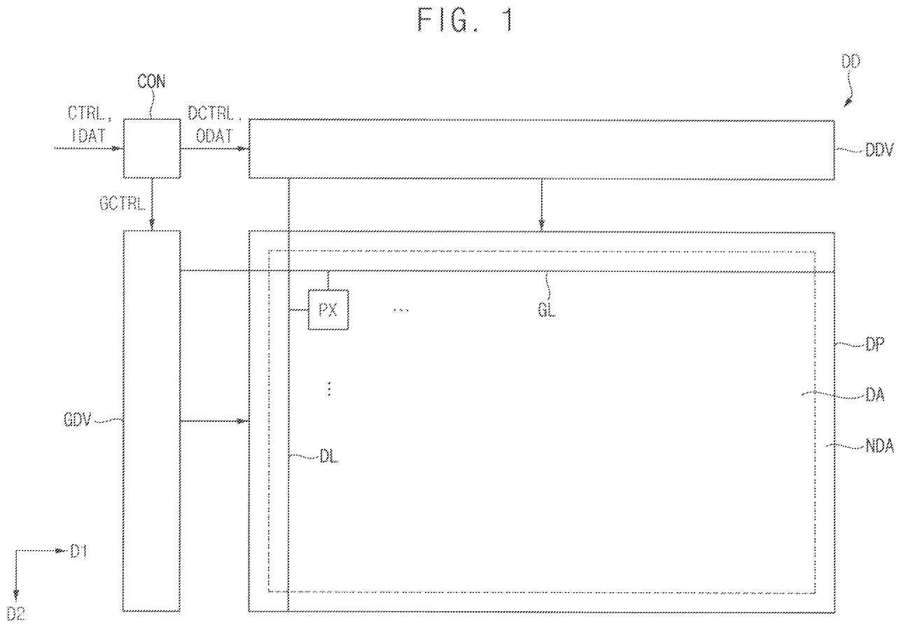

FIG. 1 is a block diagram illustrating a display device according to some embodiments.

Referring to FIG. 1, a display device DD according to some embodiments may include a display panel DP and a panel driver. The panel driver may include a driving controller CON, a gate driver GDV, and a data driver DDV.

The display panel DP may include a display area DA in which an image is displayed and a non-display area NDA positioned around the display area DA.

The display panel DP may include pixels PX, gate lines GL, and data lines DL. The pixels PX may be located in the display area DA. The pixels PX may be electrically connected to the gate lines GL and the data lines DL. The pixels PX may be arranged in a matrix arrangement of rows and columns extending along a first direction D1 and a second direction D2 crossing the first direction D1. For example, the second direction D2 may be perpendicular to the first direction D1. Each of the pixels PX may include a thin film transistor and a light emitting element. The light emitting element may generate light. The light emitting element may be an organic light emitting diode or an inorganic light emitting diode.

The gate lines GL and the data lines DL may cross each other. For example, the gate lines GL may extend in the first direction D1 and may be arranged in the second direction D2. The data lines DL may extend in the second direction D2 and may be arranged in the first direction D1.

The driving controller CON may generate a gate control signal GCTRL, a data control signal DCTRL, and an output image data ODAT based on an input image data IDAT and an input control signal CTRL provided from an external device. For example, the input image data IDAT may be RGB data including red image data, green image data, and blue image data. The input control signal CTRL may include a master clock signal and an input data enable signal. The input control signal CTRL may further include a vertical synchronization signal and a horizontal synchronization signal.

The gate driver GDV may generate gate signals based on the gate control signal GCTRL provided from the driving controller CON. For example, the gate control signal GCTRL may include a vertical start signal and a gate clock signal. The gate driver GDV may sequentially output the gate signals to the gate lines GL of the display panel DP.

The data driver DDV may generate data signals based on the data control signal DCTRL and the output image data ODAT provided from the driving controller CON. For example, the data control signal DCTRL may include an output data enable signal, a horizontal start signal, and a load signal. The data driver DDV may output the data signals to the data lines DL of the display panel DP.

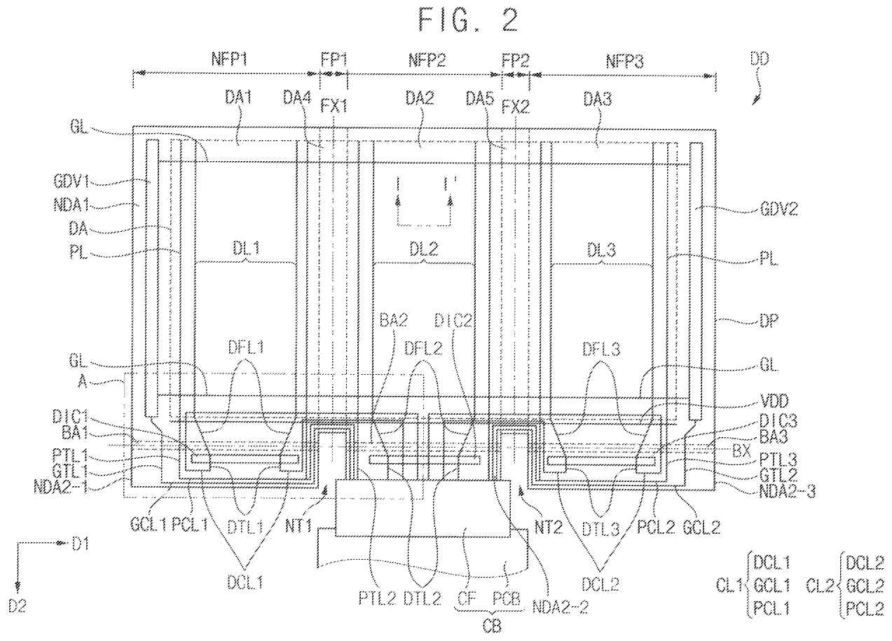

FIG. 2 is a plan view illustrating a display device according to some embodiments.

Referring to FIGS. 1 and 2, according to some embodiments, the display device DD may include a display panel DP, the panel driver, and a circuit board CB. The panel driver may include the gate driver GDV, the data driver DDV, and the driving controller CON. The gate driver GDV may include first and second gate drivers GDV1 and GDV2. The data driver DDV may include first to third data driving chips DIC1, DIC2, and DIC3.

The display panel DP (or a substrate included in the display panel DP) may include the display area DA in which the image is displayed and the non-display area NDA positioned around the display area DA.

According to some embodiments, the non-display area NDA may include a first non-display area NDA1, a bending area BA, and a second non-display area NDA2. Hereinafter, as illustrated in FIG. 2, a state in which the bending area BA of the display panel DP is not bent and unfolded will be mainly described. The second non-display area NDA2 may be spaced apart from the first non-display area NDA1 in the second direction D2. The bending area BA may be positioned between the first non-display area NDA1 and the second non-display area NDA2. The bending area BA may be bent about a bending axis BX extending in the first direction D1.

The display panel DP may include (or may have) a plurality of non-folding portions and a plurality of folding portions arranged in the first direction D1. Each of the folding portions may be located between two adjacent non-folding portions. Each of the folding portions may be folded about a folding axis extending in the second direction D2.

According to some embodiments, as illustrated in FIG. 2, the display panel DP (or the substrate included in the display panel DP) may include a first non-folding portion NFP1, a first folding portion FP1, a second non-folding portion NFP2, a second folding portion FP2, and a third non-folding portion NFP3 arranged in the first direction D1. However, embodiments according to the present disclosure are not limited thereto, and the display panel DP2 may include four or more non-folding portions and three or more folding portions. That is, the number of folding portions and non-folding portions may vary according to some embodiments, and there may be additional folding/non-folding portions than what is illustrated in FIG. 2, without departing from the spirit and scope of embodiments according to the present disclosure.

The first non-folding portion NFP1 may include a first display area DA1, a portion of the first non-display area NDA1, a first bending area BA1, and a second-second non-display area NDA2-1.

The first gate driver GDV1 may be located in the portion of the first non-display area NDA1 of the first non-folding portion NFP1. For example, the first gate driver GDV1 may be integrated in the portion of the first non-display area NDA1 of the first non-folding portion NFP1. According to some embodiments, the first non-display area NDA1 may include a fourth bending area that is positioned between the first gate driver GDV1 and the display area DA, and is bent about a bending axis extending in the second direction D2. For example, the fourth bending area may be bent such that the first gate driver GDV1 is positioned under the display area DA.

The first data driving chip DIC1 may be located in a second-first non-display area NDA2-1 of the first non-folding portion NFP1. For example, the first data driving chip DIC1 may be directly mounted on the second-first non-display area NDA2-1 of the first non-folding portion NFP1. The second-first non-display area NDA2-1 may be referred to as a first pad area. The second-first non-display area NDA2-1 may be connected to the first display area DA1 with the first bending area BA1 interposed therebetween. For example, the first bending area BA1 may be bent such that the first data driving chip DIC1 is positioned under the display area DA.

The second non-folding portion NFP2 may be spaced apart from the first non-folding portion NFP1 in the first direction D1. The second non-folding portion NFP2 may include a second display area DA2, a portion of the first non-display area NDA1, a second bending area BA2, and a second-second non-display area NDA2-2.

The second data driving chip DIC2 may be located in the second-second non-display area NDA2-2 of the second non-folding portion NFP2. For example, the second data driving chip DIC2 may be directly mounted on the second-second non-display area NDA2-2 of the second non-folding portion NFP2. The second-second non-display area NDA2-2 may be referred to as a second pad area. The second-second non-display area NDA2-2 may be connected to the second display area DA2 with the second bending area BA2 interposed therebetween. For example, the second bending area BA2 may be bent such that the second data driving chip DIC2 is positioned under the display area DA.

The third non-folding portion NFP3 may be spaced apart from the second non-folding portion NFP2 in the first direction D1. The third non-folding portion NFP3 may include a first display area DA3, a portion of the first non-display area NDA1, a third bending area BA3, and a second-third non-display area NDA2-3.

The second gate driver GDV2 may be located in the portion of the first non-display area NDA1 of the third non-folding portion NFP3. For example, the second gate driver GDV2 may be integrated in the portion of the first non-display area NDA1 of the third non-folding portion NFP3. According to some embodiments, the first non-display area NDA1 may include a fifth bending area that is positioned between the second gate driver GDV2 and the display area DA, and is bent about a bending axis extending in the second direction D2. For example, the fifth bending area may be bent such that the second gate driver GDV2 is positioned under the display area DA.

The third data driving chip DIC3 may be located in the second-third non-display area NDA2-3 of the third non-folding portion NFP3. For example, the third data driving chip DIC3 may be directly mounted in the second-third non-display area NDA2-3 of the third non-folding portion NFP3. The second-third non-display area NDA2-3 may be referred to as a third pad area. The second-third non-display area NDA2-3 may be connected to the third display area DA3 with the third bending area BA3 interposed therebetween. For example, the third bending area BA3 may be bent such that the third data driving chip DIC3 is positioned under the display area DA.

The first folding portion FP1 may be positioned between the first and second non-folding portions NFP1 and NFP2, and may be folded about a first folding axis FX1 extending in the second direction D2. The first folding portion FP1 may include a fourth display area DA4 and a portion of the first non-display area NDA1.

The second folding portion FP2 may be positioned between the second and third non-folding portions NFP2 and NFP3, and may be folded about a second folding axis FX2 extending in the second direction D2. The second folding portion FP2 may include a fifth display area DA5 and a portion of the first non-display area NDA1.

According to some embodiments, the first to fifth display areas DA1, DA2, DA3, DA4, and DA5 may be connected to each other to form a rectangular display area DA.

According to some embodiments, a first notch NT1 and a second notch NT2 may be formed in the display panel DP.

The first notch NT1 may be formed between the second-first non-display area NDA2-1 of the first non-folding portion NFP1 and the second-second non-display area NDA2-2 of the second non-folding portion NFP2. The first notch NT1 may overlap the first folding axis FX1, and may be concave in an inward direction (e.g., a direction opposite to the second direction D2 in FIG. 2) from an edge of the display panel DP in the second direction D2. The first notch NT1 may overlap the bending axis BX. That is, the second-second non-display area NDA2-2 of the second non-folding portion NFP2 may be spaced apart from the second-first non-display area of the first non-folding portion NFP1 in the first direction with the first notch NT1 interposed therebetween. The second bending area BA2 of the second non-folding portion NFP2 may be spaced apart from the first bending area BA1 of the first non-folding portion NFP1 in the first direction D1 with the first notch NT1 interposed therebetween.

The second notch NT2 may be formed between the second-second non-display area NDA2-2 of the second non-folding portion NFP2 and the second-third non-display area NDA2-3 of the third non-folding portion NFP3. The second notch NT2 may overlap the second folding axis FX2, and may be concave in an inward direction (e.g., a direction opposite to the second direction D2 in FIG. 2) from the edge of the display panel DP in the second direction D2. The second notch NT2 may overlap the bending axis BX. That is, the second-third non-display area NDA2-3 of the third non-folding portion NFP3 may be spaced apart from the second-second non-display area of the second non-folding portion NFP2 in the first direction D1 with the second notch NT2 interposed therebetween. The third bending area BA3 of the third non-folding portion NFP3 may be spaced apart from the second bending area BA2 of the second non-folding portion NFP2 in the first direction D1 with the second notch NT2 interposed therebetween.

The circuit board CB may be attached on an end portion of the display panel DP. According to some embodiments, the circuit board CB may include a connection film CF and a printed circuit board PCB. The driving controller CON may be located on the printed circuit board PCB. For example, the driving controller CON may be mounted on the printed circuit board PCB. The printed circuit board PCB may be connected to the display panel DP through the connection film CF, and may be electrically connected to the first to third data driving chips DIC1, DIC2, and DIC3, and the first and second gate drivers GDV1 and GDV2. For example, the connection film CF may be a flexible printed circuit board FPCB. Optionally, the connection film CF may be omitted.

According to some embodiments, the circuit board CB may be attached on any one of the second-first non-display area NDA2-1 of the first non-folding portion NFP1, the second-second non-display area NDA2-2 of the second non-folding portion NFP2, and the second-third non-display area NDA2-3 of the third non-folding portion NFP3. For example, as illustrated in FIG. 2, the circuit board CB may be attached only on the second-second non-display area NDA2-2 of the second non-folding portion NFP2, and may not be attached on the second-first non-display area NDA2-1 of the first non-folding portion NFP1 and the second-third non-display area NDA2-3 of the third non-folding portion NFP3. The circuit board CB may be electrically connected to the first gate driver GDV1 and the first data driving chip DIC1 positioned in the first non-folding portion NFP1 through first connection lines CL1 extending to surround the first notch NT1. The circuit board CB may be electrically connected to the second gate driver GDV2 and the third data driving chip DIC3 positioned in the third non-folding portion NFP3 through second connection lines CL2 extending to surround the second notch NT2.

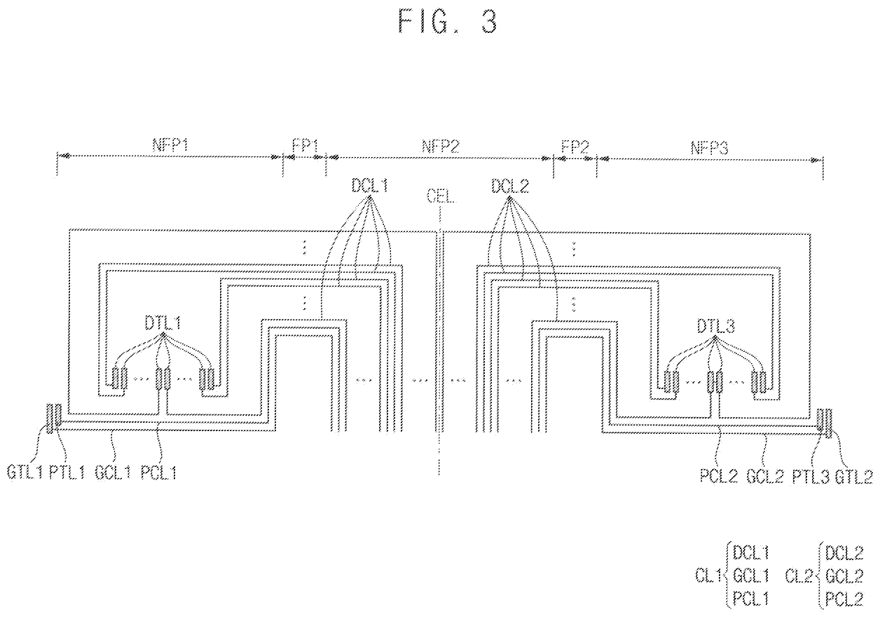

FIG. 3 is a plan view schematically illustrating connection lines included in the display device of FIG. 2.

Referring to FIGS. 1 to 3, according to some embodiments, the display panel DP may include the data lines DL, the gate lines GL, power lines PL, data fan-out lines, transmission lines, the first connection lines CL1, and the second connection lines CL2.

The first connection lines CL1 may overlap the first non-folding portion NFP1, the first folding portion FP1, and the second non-folding portion NFP2. The first connection lines CL1 may extend to surround the first notch NT1. The first connection lines CL1 may include first data connection lines DCL1, a first gate connection line GCL1, and a first power connection line PCL1.

The second connection lines CL2 may overlap the second non-folding portion NFP2, the second folding portion FP2, and the third non-folding portion NFP3. The second connection lines CL2 may extend to surround the second notch NT2. The second connection lines CL2 may include second data connection lines DCL2, a second gate connection line GCL2, and a second power connection line PCL2.

The data lines DL may extend in the second direction D2, and may be arranged in the first direction D1. The data lines DL may transmit the data signals provided from the first to third data driving chips DIC1, DIC2, and DIC3 to the pixels PX.

According to some embodiments, the data lines DL may include first data lines DL1 electrically connected to the first data driving chip DIC1, second data lines DL2 electrically connected to the second data driving chip DIC, and. third data lines DL3 electrically connected to the third data driving chip DIC3. The first data lines DL1 may be located in the first display area DA1. Some of the first data lines DL1 may also be located in the fourth display area DA4 adjacent to the first display area DA1. The second data lines DL2 may be located in the second display area DA2. Some of the second data lines DL2 may also be located in the fourth and fifth display areas DA4 and DA5 adjacent to the second display area DA2. The third data lines DL3 may be located in the third display area DA3. Some of the third data lines DL3 may also be located in the fifth display area DA5 adjacent to the third display area DA3.

The first data lines DL1 may be electrically connected to the first data driving chip DIC1 through first data fan-out lines DFL1. The first data fan-out lines DFL1 may be located in the first non-display area NDA1, the first bending area BA1, and the second-first non-display area NDA2-1. The second data lines DL2 may be electrically connected to the second data driving chip DIC2 through second data fan-out lines DFL2. The second data fan-out lines DFL2 may be located in the first non-display area NDA1, the second bending area BA2, and the second-second non-display area NDA2-2. The third data lines DL3 may be electrically connected to the third data driving chip DIC3 through third data fan-out lines DFL3. The third data fan-out lines DFL3 may be located in the first non-display area NDA1, the third bending area BA3, and the second-third non-display area NDA2-3.

As described above, the circuit board CB may be attached only on the second-second non-display area NDA2-2 of the second non-folding portion NFP2, and may not be attached on the second-first non-display area NDA2-1 of the first non-folding portion NFP1 and the second-third non-display area NDA2-3 of the third non-folding portion NFP3.

The first data driving chip DIC1 located in the second-first non-display area NDA2-1 of the first non-folding portion NFP1 may be electrically connected to the circuit board CB through first data transmission lines DTL1 and the first data connection lines. Each of the first data transmission lines DTL1 may overlap the first non-folding portion NFP1. Each of the first data connection lines DCL1 may overlap the first non-folding portion NFP1, the first folding portion FP1, and the second non-folding portion NFP2. For example, each of the first data connection lines DCL1 may extend to surround the first notch NT1.

The second data driving chip DIC2 located in the second-second non-display area NDA2-2 of the second non-folding portion NFP2 may be electrically connected to the circuit board CB through second data transmission lines DTL2. Each of the second data transmission lines DTL2 may overlap the second non-folding portion NFP2.

The third data driving chip DIC3 located in the second-third non-display area NDA2-3 of the third non-folding portion NFP3 may be electrically connected to the circuit board CB through third data transmission lines DTL3 and the second data connection lines DCL2. Each of the third data transmission lines DTL3 may overlap the third non-folding portion NFP3. Each of the second data connection lines DCL2 may overlap the second non-folding portion NFP2, the second folding portion FP2, and the third non-folding portion NFP3. For example, each of the second data connection lines DCL2 may extend to surround the second notch NT2.

According to some embodiments, at least some of the first data fan-out lines DFL1, the second data fan-out lines DFL2, the third data fan-out lines DFL3, the first data connection lines DCL1, and the second data connection lines DCL2 may be arranged to partially overlap to the display area DA. In this case, dead space may be minimized or reduced by reducing an area of the first non-display area NDA1.

The gate lines GL may extend in the first direction D1, and may be arranged in the second direction D2. The gate lines GL may transfer the gate signals provided from the first and second gate drivers GDV1 and GDV2 to the pixels PX.

The first gate driver GDV1 located in the portion of the first non-display area NDA1 of the first non-folding portion NFP1 may be electrically connected to the circuit board CB through a first gate transmission line GTL1 and the first gate connection line GCL1. The first gate transmission line GTL1 may overlap the first non-folding portion NFP1. The first gate connection line GCL1 may overlap the first non-folding portion NFP1, the first folding portion FP1, and the second non-folding portion NFP2. For example, the first gate connection line GCL1 may extend to surround the first notch NT1.

The second gate driver GDV2 located in the portion of the first non-display area NDA1 of the third non-folding portion NFP3 may be electrically connected to the circuit board CB through a second gate transmission line GTL2 and the second gate connection line GCL2. The second gate transmission line GTL2 may overlap the third non-folding portion NFP3. The second gate connection line GCL2 may overlap the second non-folding portion NFP2, the second folding portion FP2, and the third non-folding portion NFP3. For example, the second gate connection line GCL2 may extend to surround the second notch NT2.

The power lines PL may extend in the second direction D2, and may be arranged in the first direction D1. The power lines PL may be connected to a driving voltage line VDD extending in the first direction D1. The power lines PL may transfer a driving voltage provided from the driving voltage line VDD to the pixels PX.

The driving voltage line VDD may overlap the first to third non-folding portions NFP1, NFP2, and NFP3. A portion of the driving voltage line VDD overlapping the first non-folding portion NFP1 may be electrically connected to the circuit board CB through a first power transmission line PTL1 and a first power connection line PCL1. The first power transmission line PTL1 may overlap the first non-folding portion NFP1. For example, a plurality of first power transmission lines PTL1 may be provided. The first power connection line PCL1 may overlap the first non-folding portion NFP1, the first folding portion FP1, and the second non-folding portion NFP2. For example, the first power connection line PCL1 may extend to surround the first notch NT1.

A portion of the driving voltage line VDD overlapping the second non-folding portion NFP2 may be electrically connected to the circuit board CB through a second power transmission line PTL2. The second power transmission line PTL2 may overlap the first non-folding portion NFP2. For example, a plurality of second power transmission lines PTL2 may be provided.

A portion of the driving voltage line VDD overlapping the third non-folding portion NFP3 may be electrically connected to the circuit board CB through a third power transmission line PTL3 and a second power connection line PCL2. The third power transmission line PTL3 may overlap the third non-folding portion NFP3. For example, a plurality of third power transmission lines PTL3 may be provided. The second power connection line PCL2 may overlap the second non-folding portion NFP2, the second folding portion FP2, and the third non-folding portion NFP3. For example, the second power connection line PCL2 may extend to surround the second notch NT2.

According to some embodiments, as illustrated in FIG. 3, a virtual center line CEL extending in the second direction D2 across a center of the second non-folding portion NFP2 may be defined. The first data connection lines DCL1 may be symmetrical with the second data connection lines DCL2 with respect to the virtual center line CEL. The first gate connection line GCL1 may be symmetrical with the second gate connection line GCL2 with respect to the virtual center line CEL. The first power connection line PCL1 may be symmetrical with the second power connection line PCL2 with respect to the virtual center line CEL. However, this is exemplary and embodiments are not limited thereto.

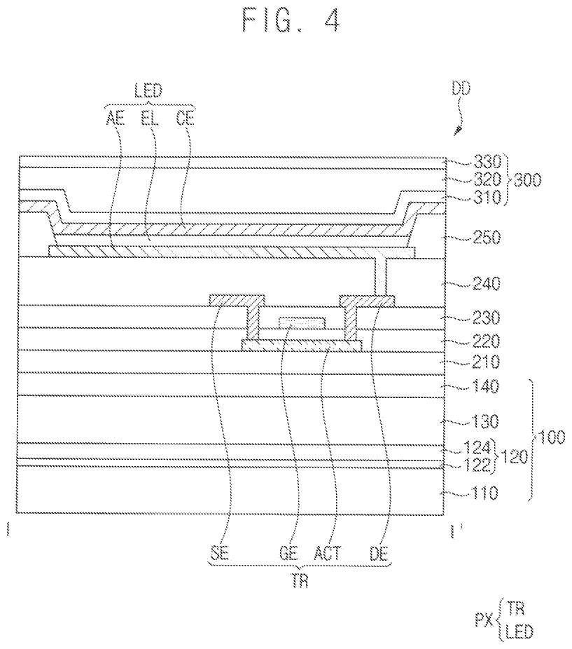

FIG. 4 is a cross-sectional view taken along line I-I′ of FIG. 2.

Referring to FIGS. 2 and 4, according to some embodiments, the display device DD (or the display panel DP included in the display device DD) may include a substrate 100, a buffer layer 210, the pixels PX, and an encapsulation layer 300. Each of the pixels PX may include a thin film transistor TR and a light emitting element LED.

The substrate 100 may have flexibility. According to some embodiments, the substrate 100 may include a first resin layer 110, a first barrier layer 120, a second resin layer 130, and a second barrier layer 140.

The first resin layer 110 may include a polymer resin. Examples of the polymer resin may include polyimide (PI), polyethersulphone (PES), polyacrylate (PA), polyetherimide (PEI), polyethylene naphthalate (PEN), polyethylene terephthalate (PET), polyphenylene sulfide (PPS), polyarylate (PAR), polycarbonate (PC), cellulose acetate propionate (CAP), or the like. These can be used alone or in a combination thereof.

The first barrier layer 120 may be located on the first resin layer 110. The first barrier layer 120 may be located between the first resin layer 110 and the second resin layer 130. The first barrier layer 120 may include an inorganic material. Accordingly, the first barrier layer 120 may prevent or reduce impurities such as oxygen or moisture from penetrating into the second resin layer 130 through the first resin layer 110 from an outside (e.g., from a lower portion of the first resin layer 110). Examples of the inorganic material may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These can be used alone or in a combination thereof.

According to some embodiments, the first barrier layer 120 may include a first lower barrier layer 122 and a first upper barrier layer 124. The first upper barrier layer 124 may be located between the first lower barrier layer 122 and the second resin layer 130. A thickness of the first lower barrier layer 122 may be less than a thickness of the first upper barrier layer 124. As will be described later, the first and second connection lines CL1 and CL2 may be located between the first lower barrier layer 122 and the first upper barrier layer 124. The first lower barrier layer 122 and the first upper barrier layer 124 may serve to improve adhesion to the first and second connection lines CL1 and CL2.

The second resin layer 130 may be located on the first barrier layer 120. The second resin layer 130 may include a polymer resin. For example, the second resin layer 130 may include substantially the same material as the first resin layer 110.

The second barrier layer 140 may be located on the second resin layer 130. The second barrier layer 140 may be located between the second resin layer 130 and the buffer layer 210. The second barrier layer 140 may include an inorganic insulating material.

The buffer layer 210 may be located on the second barrier layer 140. The buffer layer 210 may prevent or reduce impurities such as oxygen or moisture from penetrating into an upper portion of the substrate 100 through the substrate 100. The buffer layer 210 may include an inorganic material. According to some embodiments, the buffer layer 210 may be entirely formed in the display area DA and the non-display area NDA.

An active layer ACT may be located on the buffer layer 210. The active layer ACT may include an oxide semiconductor, a silicon semiconductor, an organic semiconductor, or the like. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a source area, a drain area, and a channel area positioned between the source area and the drain area.

A first insulating layer 220 may be located on the active layer ACT. The first insulating layer 220 may cover the active layer ACT on the buffer layer 210. The first insulating layer 220 may include an inorganic insulating material. According to some embodiments, the first insulating layer 220 may be entirely formed in the display area DA and the non-display area NDA. The first insulating layer 220 may be referred to as a gate insulating layer.

A gate electrode GE may be located on the first insulating layer 220. The gate electrode GE may overlap the channel area of the active layer ACT. The gate electrode GE may include a conductive material such as a metal, an alloy, a conductive metal nitride, a conductive metal oxide, a transparent conductive material, or the like. Examples of the conductive material may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These can be used alone or in a combination thereof. The gate electrode GE may have a single-layered structure or a multi-layered structure including a plurality of conductive layers.

A second insulating layer 230 may be located on the gate electrode GE. The second insulating layer 230 may cover the gate electrode GE on the first insulating layer 220. The second insulating layer 230 may include an inorganic insulating material. According to some embodiments, the second insulating layer 230 may be entirely formed in the display area DA and the non-display area NDA. The second insulating layer 230 may be referred to as an interlayer insulating layer.

A source electrode SE and a drain electrode DE may be located on the second insulating layer 230. The source electrode SE and the drain electrode DE may be connected to the source area and the drain area of the active layer ACT, respectively. Each of the source electrode SE and the drain electrode DE may include a conductive material. The active layer ACT, the gate electrode GE, the source electrode SE, and the drain electrode DE may form the thin film transistor TR.

A third insulating layer 240 may be located on the source electrode SE and the drain electrode DE. The third insulating layer 240 may cover the source electrode SE and the drain electrode DE on the second insulating layer 230. The third insulating layer 240 may include an organic insulating material. According to some embodiments, the third insulating layer 240 may be formed only in the display area DA and a portion of the first non-display area NDA1 adjacent to the display area DA. The third insulating layer 240 may be referred to as a via insulating layer.

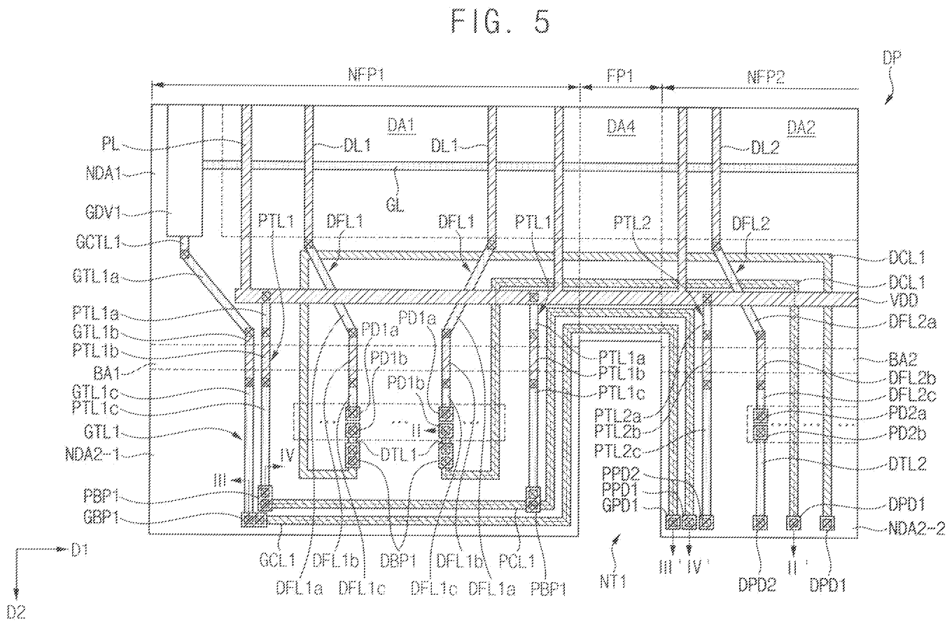

FIG. 5 illustrates that three conductive layers and three insulating layers are located between the buffer layer 210 and an anode electrode AE, but embodiments are not limited thereto. For example, four or more conductive layers and four or more insulating layers may be located between the buffer layer 210 and the anode electrode AE.

The anode electrode AE may be located on the third insulating layer 240. The anode electrode AE may include a conductive material. The anode electrode AE may be connected to the drain electrode DE through a contact hole formed in the third insulating layer 240. Accordingly, the anode electrode AE may be electrically connected to the thin film transistor TR.

A fourth insulating layer 250 may be located on the anode electrode AE. The fourth insulating layer 250 may cover a peripheral portion of the anode electrode AE, and may define a pixel opening exposing a central portion of the anode electrode AE. The fourth insulating layer 250 may include an organic material. According to some embodiments, the fourth insulating layer 250 may be formed only in the display area DA and a portion of the first non-display area NDA1 adjacent to the display area DA. The fourth insulating layer 250 may be referred to as a pixel defining layer.

An emission layer EL may be located on the anode electrode AE. The emission layer EL may be located in the pixel opening of the fourth insulating layer 250. According to some embodiments, the emission layer EL may include at least one of an organic light emitting material or quantum dot.

According to some embodiments, the organic light emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

According to some embodiments, the quantum dot may include a core including a Group II-VI compound, a Group III-V compound, a Group IV-VI compound, a Group IV element, and/or a Group IV compound. According to some embodiments, the quantum dot may have a core-shell structure including the core and a shell surrounding the core. The shell may serve as a protection layer for preventing or reducing instances of the core being chemically denatured to maintain semiconductor characteristics, and may serve as a charging layer for imparting electrophoretic characteristics to the quantum dot.

A cathode electrode CE may be located on the emission layer EL. The cathode electrode CE may also be located on the fourth insulating layer 250. The cathode electrode CE may include a conductive material. The anode electrode AE, the emission layer EL, and the cathode electrode CE may form the light emitting element LED.

The encapsulation layer 300 may be located on the cathode electrode CE. The encapsulation layer 300 may include at least one inorganic encapsulation layer and at least one organic encapsulation layer. According to some embodiments, the encapsulation layer 300 may include a first inorganic encapsulation layer 310 located on the cathode electrode CE, an organic encapsulation layer 320 located on the first inorganic encapsulation layer 310, and a second inorganic encapsulation layer 330 located on the organic encapsulation layer 320.

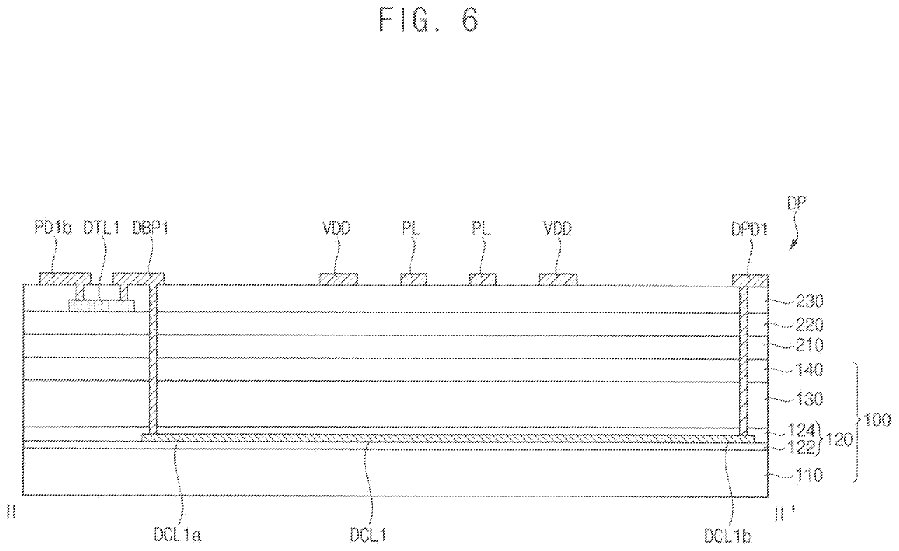

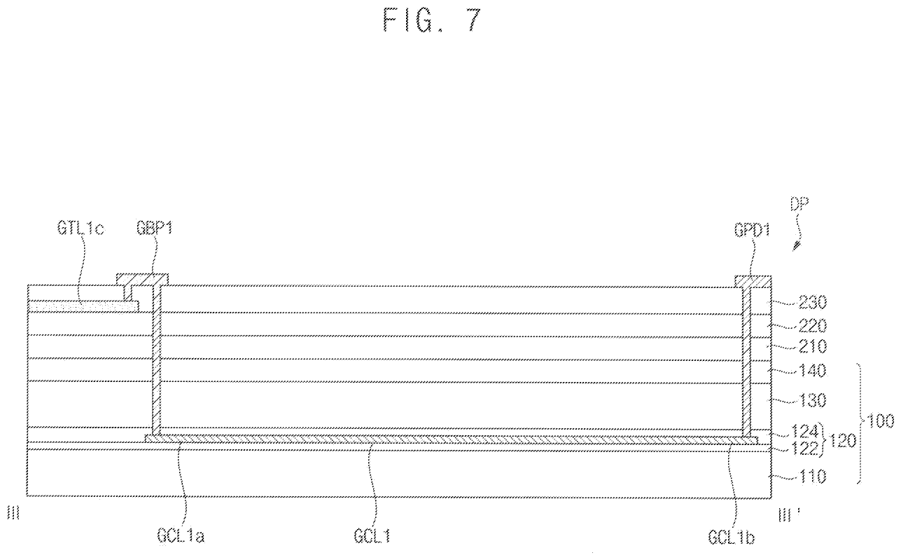

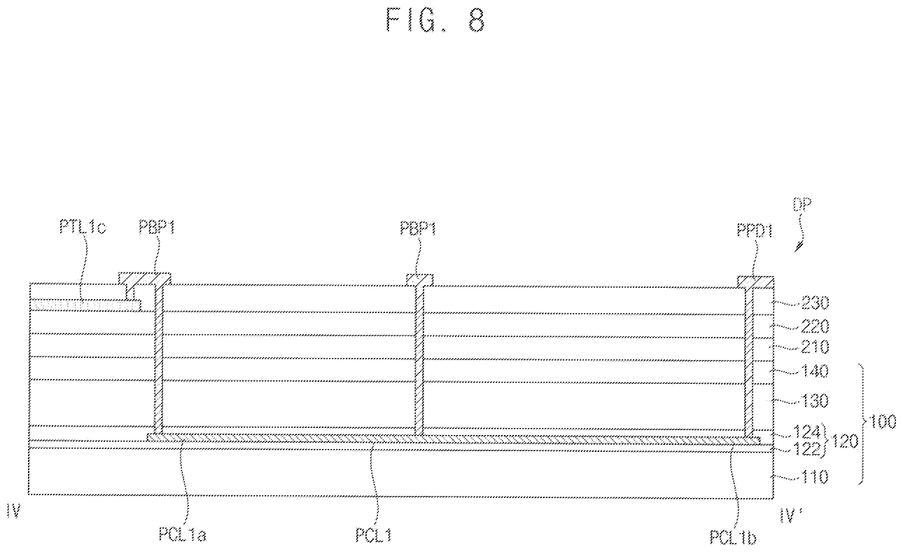

FIG. 5 is an enlarged plan view of area ‘A’ of a display panel included in the display device of FIG. 2. FIG. 6 is a cross-sectional view taken along line II-II′ of FIG. 5. FIG. 7 is a cross-sectional view taken along line III-III′ of FIG. 5. FIG. 8 is a cross-sectional view taken along line IV-IV′ of FIG. 5.

Hereinafter, a plurality of lines included in the display panel DP will be described in more detail with reference to FIGS. 1 to 8. In the following description, descriptions corresponding to the first non-folding area NFP1 may be substantially equally applied to the third non-folding area NFP3. For example, descriptions of the first data connection lines DLC1 may be substantially equally applied to the corresponding second data connection lines DLC2, and other lines are also the same.

Referring to FIGS. 1 to 8, according to some embodiments, the data lines DL may be located on the same layer as the source electrode SE and the drain electrode DE, but embodiments are not limited thereto.

According to some embodiments, each of the first data fan-out lines DFL1 may include a first portion DFL1a, a second portion DFL1b, and a third portion DFL1c. The first portion DFL1a may be positioned in the first non-display area NDA1, and may be electrically connected to the corresponding first data line DL1 through a contact hole. The second portion DFL1b may cross the first bending area BA1, and may connect the first portion DFL1a and the third portion DFL1c. The third portion DFL1c may be positioned in the second-first non-display area NDA2-1, and may be electrically connected to the corresponding first-first pad PD1a through a contact hole. For example, the first portion DFL1a and the third portion DFL1c of each of the first data fan-out lines DFL1 may be located on the same layer as the gate electrode GE, and the second portion DFL1b of each of the first data fan-out lines DFL1 and the first-first pads PD1a may be located on the same layer as the source electrode SE and the drain electrode DE, but embodiments are not limited thereto.

The first data driving chip DIC1 may be electrically connected to the first-first pads PD1a arranged in the first direction D1 and first-second pads PD1b spaced apart from the first-first pads PD1a in the second direction D2.

Each of the first data transmission lines DTL1 may be positioned in the second-first non-display area NDA2-1, and may be electrically connected to the corresponding first-second pad PD1b through a contact hole. For example, the first data transmission lines DTL1 may be located on the same layer as the gate electrode GE, and the first-second pads PD1b may be located on the same layer as the source electrode SE and the drain electrode DE, but embodiments are not limited thereto.

The first data connection lines DCL1 may be located between the first lower barrier layer 122 and the first upper barrier layer 124.

Each of the first data connection lines DCL1 may include a first end portion DCL1a and a second end portion DCL1b opposite to the first end portion DCL1a. The first end portion DCL1a of each of the first data connection lines DCL1 may be positioned in the second-first non-display area NDA2-1, and may be electrically connected to the corresponding first data transmission line DTL1 through a first data bridge pattern DBP1. The second end portion DCL1b of each of the first data connection lines DCL1 may be positioned in the second-second non-display area NDA2-2, and may be electrically connected to the corresponding first data pad DPD1 through a contact hole. For example, the first data bridge patterns DBP1 and the first data pads DPD1 may be located on the same layer as the source electrode SE and the drain electrode DE, but embodiments are not limited thereto.

The second data fan-out lines DFL2 may be substantially the same as or similar to the first data fan-out lines DFL1. The second data driving chip DIC2 may be electrically connected to second second-first pads PD2a arranged in the first direction D1 and second-second pads PD2b spaced apart from the second-first pads PD2a in the second direction D2.

The second data transmission lines DTL2 may be positioned in the second-second non-display area NDA2-2. A first end portion of each of the second data transmission lines DTL2 may be electrically connected to the corresponding second-second pad PD2b through a contact hole. A second end portion of each of the second data transmission lines DTL2 may be electrically connected to a corresponding second data pad DPD2 through a contact hole. For example, the second data transmission lines DTL2 may be located on the same layer as the gate electrode GE, and the second data pads DPD2 may be located on the same layer as the source electrode SE and the drain electrode DE, but embodiments are not limited thereto.

The first data pads DPD1 electrically connected to the first data driving chip DIC1 and the second data pads DPD2 electrically connected to the second data driving chip DIC2 may be located in the second-second non-display area NDA2-2 to not overlap each other. For example, the first data pads DPD1 and the second data pads DPD2 may be arranged in a zigzag shape, but embodiments are not limited thereto.

The circuit board CB may be electrically connected to the first data pads DPD1, the second data pads DPD2, and third data pads. The first data driving chip DIC1 may receive the data control signal DCTRL and the output image data ODAT from the driving controller located on the circuit board CB through the first data pads DPD1, the first data connection lines DCL1, and the first data transmission lines DTL1. The second data driving chip DIC2 may receive the data control signal DCTRL and the output image data ODAT from the driving controller located on the circuit board CB through the second data pads DPD2 and the second data transmission lines DTL2. The third data driving chip DIC3 may receive the data control signal DCTRL and the output image data ODAT from the driving controller located on the circuit board CB through the third data pads DPD3, the second data connection lines DCL2, and the third data transmission lines DTL3.

According to some embodiments, the gate lines GL may be located on the same layer as the gate electrode GE, and a first gate control line GCTL1 connected to the first gate driver GDV1 may be located on the same layer as the source electrode SE and the drain electrode DE, but embodiments are not limited thereto.

According to some embodiments, the first gate transmission line GTL1 may include a first portion GTL1a, a second portion GTL1b, and a third portion GTL1c. The first portion GTL1a may be positioned in the first non-display area NDA1, and may be electrically connected to the first gate control line GCTL1 through a contact hole. The second portion GTL1b may cross the first bending area BA1, and may connect the first portion GTL1a and the third portion GTL1c. The third portion GTL1c may be positioned in the second-first non-display area NDA2-1. For example, the first portion GTL1a and the third portion GTL1c may be located on the same layer as the gate electrode GE, and the second portion GTL1b may be located on the same layer as the source electrode SE and the drain electrode DE, but embodiments are not limited thereto.

The first gate connection line GCL1 may be located between the first lower barrier layer 122 and the first upper barrier layer 124. That is, the first gate connection line GCL1 may be located on the same layer as the first data connection lines DCL1.

The first gate connection line GCL1 may include a first end portion GCL1a and a second end portion GCL1b opposite to the first end portion GCL1a. The first end portion GCL1a of the first gate connection line GCL1 may be positioned in the second-first non-display area NDA2-1, and may be electrically connected to the third portion GTL1c of the first gate transmission line GTL1 through a first gate bridge pattern GBP1. The second end portion GCL1b of the first gate connection line GCL1 may be positioned in the second-second non-display area NDA2-2, and may be electrically connected to a first gate pad GPD1 through a contact hole. For example, the first gate bridge pattern GBP1 and the first gate pad GPD1 may be located on the same layer as the source electrode SE and the drain electrode DE, but embodiments are not limited thereto.

The circuit board CB may be electrically connected to the first gate pad GPD1 and a second gate pad. The first gate driver GDV1 may receive the gate control signal GCTRL from the driving controller CON located on the circuit board CB through the first gate pad GPD1, the first gate connection line GCL1, the first gate transmission line GTL1, and the first gate control line GCTL1. The second gate driver GDV2 may receive the gate control signal GCTRL from the driving controller CON located on the circuit board CB through the second gate pad, the second gate connection line GCL2, the second gate transmission line GTL2, and a second gate control line.

According to some embodiments, the driving voltage line VDD and the power lines PL may be located on the same layer as the source electrode SE and the drain electrode DE, but embodiments are not limited thereto.

According to some embodiments, the first power transmission line PTL1 may include a first portion PTL1a, a second portion PTL1b, and a third portion PTL1c. The first portion PTL1a may be positioned in the first non-display area NDA1, and may be electrically connected to the driving voltage line VDD through a contact hole. The second portion PTL1b may cross the first bending area BA1, and may connect the first portion PTL1a and the third portion PTL1c. The third portion PTL1c may be positioned in the second-first non-display area NDA2-1. For example, the first portion PTL1a and the third portion PTL1c may be located on the same layer as the gate electrode GE, and the second portion PTL1b may be located on the same layer as the source electrode SE and the drain electrode DE, but embodiments are not limited thereto.

The first power connection line PCL1 may be located between the first lower barrier layer 122 and the first upper barrier layer 124. That is, the first power connection line PCL1 may be located on the same layer as the first data connection lines DCL1.

The first power connection line PCL1 may include a first end portion PCL1a and a second end portion PCL1b opposite to the first end portion PCL1a. The first end portion PCL1a of the first power connection line PCL1 may be positioned in the second-first non-display area NDA2-1, and may be electrically connected to the third portion PTL1c of the first power transmission line PTL1 through a first power bridge pattern PBP1. The second end portion PCL1b of the first power connection line PCL1 may be positioned in the second-second non-display area NDA2-2, and may be electrically connected to a first power pad PPD1 through a contact hole. For example, the first power bridge pattern PBP1 and the first power pad PPD1 may be located on the same layer as the source electrode SE and the drain electrode DE, but embodiments are not limited thereto.

According to some embodiments, as illustrated in FIG. 5, two first power transmission lines PTL1 may be located on both sides of the first non-folding area NFP1. In this case, each of the two first power transmission lines PTL1 may be electrically connected to one first power connection line PCL1 through the first power bridge pattern PBP1.

According to some embodiments, the second power transmission line PTL2 may include a first portion PTL2a, a second portion PTL2b, and a third portion PTL2c. A first end portion of the third portion PTL2c of the second power transmission line PTL2 may be electrically connected to the second portion PTL2b through a contact hole. A second end portion of the third portion PTL2c of the second power transmission line PTL2 may be electrically connected to a second power pad PPD2 through a contact hole. For example, the second power pad PPD2 may be located on the same layer as the source electrode SE and the drain electrode DE.

According to some embodiments, two second power transmission lines PTL2 may be located on both sides of the second non-folding area NFP2. In this case, two second power pads PPD2 may be located on both sides of the second non-folding area NFP2.

The circuit board CB may be electrically connected to the first power pad PPD1, the second power pad PPD2, and a third power pad.

According to some embodiments, at least one insulating layer may be located in the non-display area NDA on the second insulating layer 230. The insulating layer may cover the driving voltage line VDD, the second portion DFL1b of the first data fan-out line DFL1, the second portion DFL2b of the second data fan-out line DFL2, the second portion GTL1b of the first gate transmission line GTL1, the second portion PTL1b of the first power transmission line PTL1, the first data bridge patterns DBP1, the first gate bridge pattern GBP1, and the first power bridge pattern PBP1. The insulating layer may expose each of the first-first pads PD1a, the first-second pads PD1b, the second-first pads PD2a, the second-second pads PD2b, the first data pads DPD1, the second data pads DPD2, the first power pads PPD1, the second power pads PPD2, and the first gate pad GPD1.

According to some embodiments, the display panel DP may include the first non-folding portion NFP1, the first folding portion FP1, the second non-folding portion NFP2, the second folding portion FP2, and the third non-folding portion NFP3 which are arranged in the first direction D1. The first to third data driving chips DIC1, DIC2, and DIC3 may be respectively mounted on end portions of the first to third non-folding portions NFP1, NFP2, and NFP3 in the second direction D2 (the second-first to second-third non-display areas NDA2-1, NDA2-2, and NDA2-3). Accordingly, the display device DD may have a high resolution and may be driven at a high speed.

If a plurality of circuit boards are attached on the first to third non-folding portions NFP1, NFP2, and NFP3 of the display panel DP, respectively, an interference phenomenon may occur between the circuit boards when the display device DD is folded. In addition, an interference phenomenon may occur between connection films attached on the circuit boards to electrically connect the circuit boards. However, according to some embodiments, the circuit board CB electrically connected to the first to third data driving chips DIC1, DIC2 and DIC3 may be attached on any one of the first to third non-folding portions NFP1, NFP2, and NFP3. For example, the circuit board CB may be attached on only the second non-folding portion NFP2. The circuit board CB may be electrically connected to the first data driving chip DIC1 and the first gate driver GDV1 located in the first non-folding portion NFP1 through the first connection lines CL1 included in the display panel DP. The circuit board CB may be electrically connected to the third data driving chip DIC3 and the second gate driver GDV2 located in the third non-folding portion NFP3 through the second connection lines CL2 included in the display panel DP. Accordingly, a reliability of the display device DD may be improved even when the display device DD is folded.

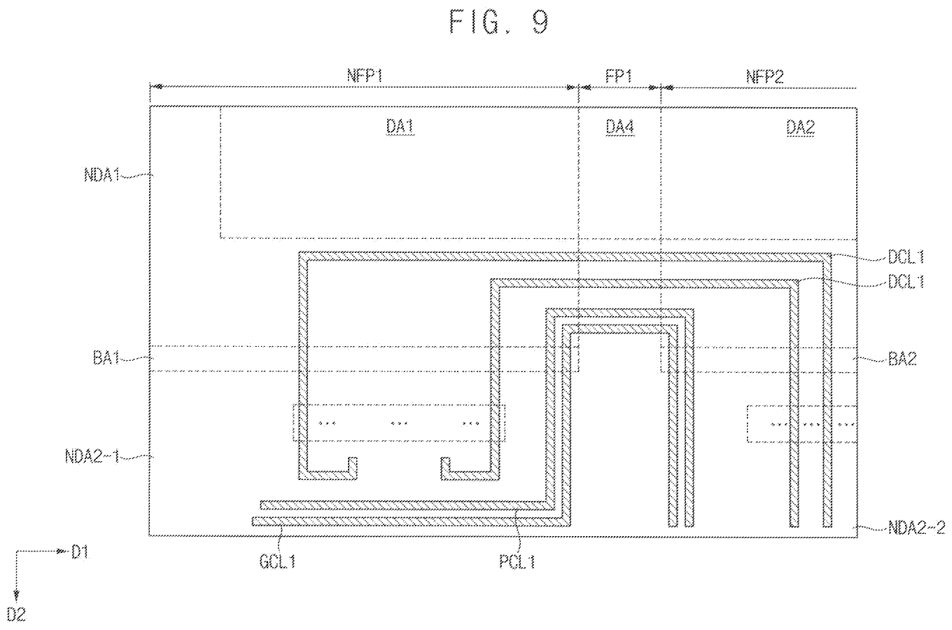

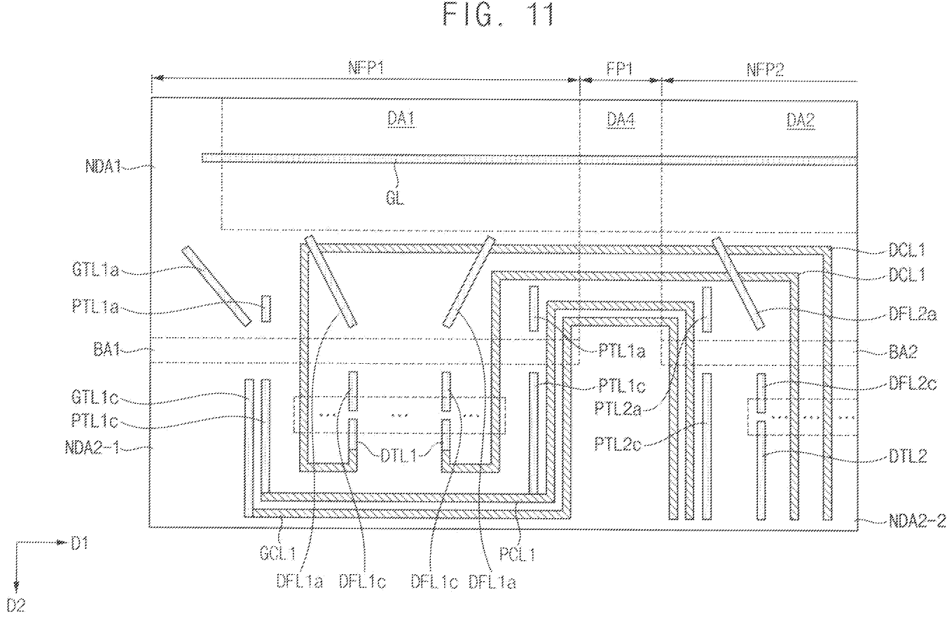

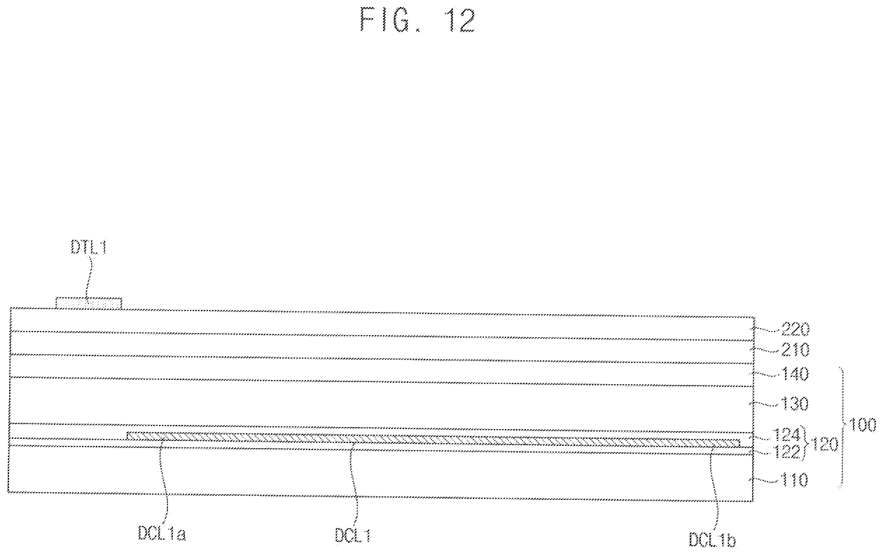

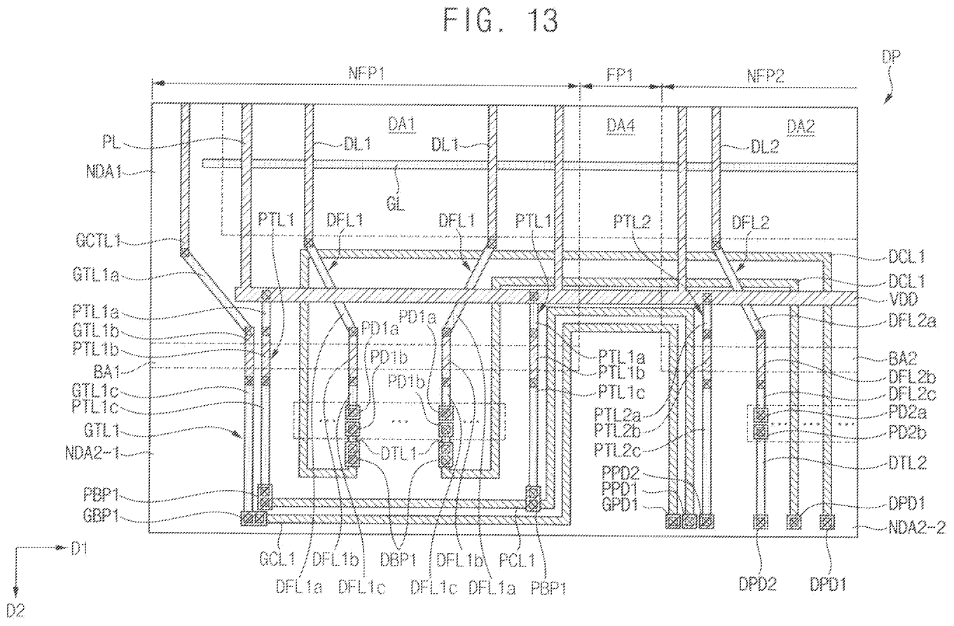

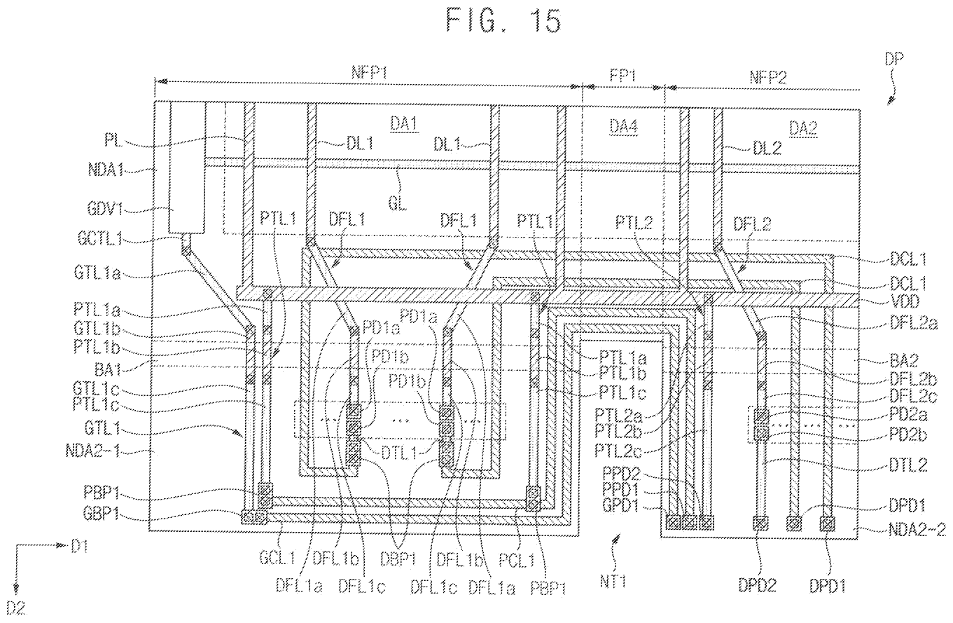

FIGS. 9 to 15 are views illustrating a method of manufacturing a display device according to some embodiments.

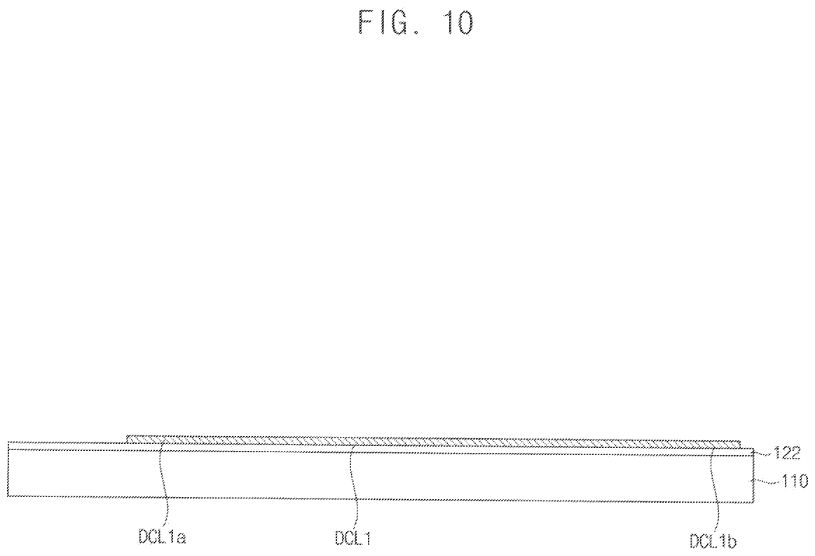

Referring to FIGS. 9 to 15 may illustrate a method of manufacturing the display device DD according to embodiments described with reference to FIGS. 1 to 8. Accordingly, repeated descriptions may be omitted or simplified. In addition, FIGS. 9, 11, 13 and 15 may correspond to FIG. 5, and FIGS. 10, 12 and 14 may correspond to FIG. 6. In the following description, descriptions corresponding to the first non-folding area NFP1 may be substantially equally or similarly applied to the third non-folding area NFP3.

Referring to FIGS. 2, 4, 9 and 10, first, the first lower barrier layer 122 may be formed on the first resin layer 110. The first resin layer 110 may include the display area DA and the non-display area NDA. The first lower barrier layer 122 may be entirely formed in the display area DA and the non-display area NDA.

The first data connection lines DCL1, the first gate connection line GCL1, and the first power connection line PCL1 may be formed in the non-display area NDA on the first lower barrier layer 122. For example, a conductive material layer may be formed on the first lower barrier layer 122. Subsequently, the first data connection lines DCL1, the first gate connection line GCL1, and the first power connection line PCL1 may be substantially simultaneously formed by patterning the conductive material layer.

Referring to FIGS. 2, 4, 11 and 12, the first upper barrier layer 124 may be formed on the first lower barrier layer 122. The first upper barrier layer 124 may be entirely formed in the display area DA and the non-display area NDA. The first upper barrier layer 124 may cover the first data connection lines DCL1, the first gate connection line GCL1, and the first power connection line PCL1.

The second resin layer 130, the second barrier layer 140, and the buffer layer 210 may be formed on the first upper barrier layer 124. Each of the second resin layer 130, the second barrier layer 140, and the buffer layer 210 may be entirely formed in the display area DA and the non-display area NDA.

The active layer ACT may be formed in the display area DA on the buffer layer 210.

The first insulating layer 220 may be formed on the buffer layer 210. The first insulating layer 220 may be entirely formed in the display area DA and the non-display area NDA. The first insulating layer 220 may cover the active layer ACT.

The gate electrode GE and the gate lines GL may be formed in the display area DA on the first insulating layer 220. The first portions DFL1a and DFL2a and the third portions DFL1c and DFL2c of the first and second data fan-out lines DFL1 and DFL2, the first and second data transmission lines DTL1 and DTL2, the first portion GTL1a and the third portion GTL1c of the first gate transmission line GTL1, and the first portions PTL1a and PTL2a and the third portions PTL1c and PTL2c of the first and second power transmission lines PTL1 and PTL2 may be formed in the non-display area NDA on the first insulating layer 220. For example, a conductive material layer may be entirely formed in the display area DA and the non-display area NDA on the first insulating layer 220. Subsequently, the gate electrode GE, the gate lines GL, the first portions DFL1a and DFL2a and the third portions DFL1c and DFL2c of the first and second data fan-out lines DFL1 and DFL2, the first and second data transmission lines DTL1 and DTL2, the first portion GTL1a and the third portion GTL1c of the first gate transmission line GTL1, and the first portions PTL1a and PTL2a and the third portions PTL1c and PTL2c of the first and second power transmission lines PTL1 and PTL2 may be substantially simultaneously (or concurrently) formed by patterning the conductive material layer.

Referring to FIGS. 2, 4, 13 and 14, the second insulating layer 230 may be formed on the first insulating layer 220. The second insulating layer 230 may be entirely formed in the display area DA and the non-display area NDA. The second insulating layer 230 may cover the gate electrode GE, the gate lines GL, the first portions DFL1a and DFL2a and the third portions DFL1c and DFL2c of the first and second data fan-out lines DFL1 and DFL2, the first and second data transmission lines DTL1 and DTL2, the first portion GTL1a and the third portion GTL1c of the first gate transmission line GTL1, and the first portions PTL1a and PTL2a and the third portions PTL1c and PTL2c of the first and second power transmission lines PTL1 and PTL2.

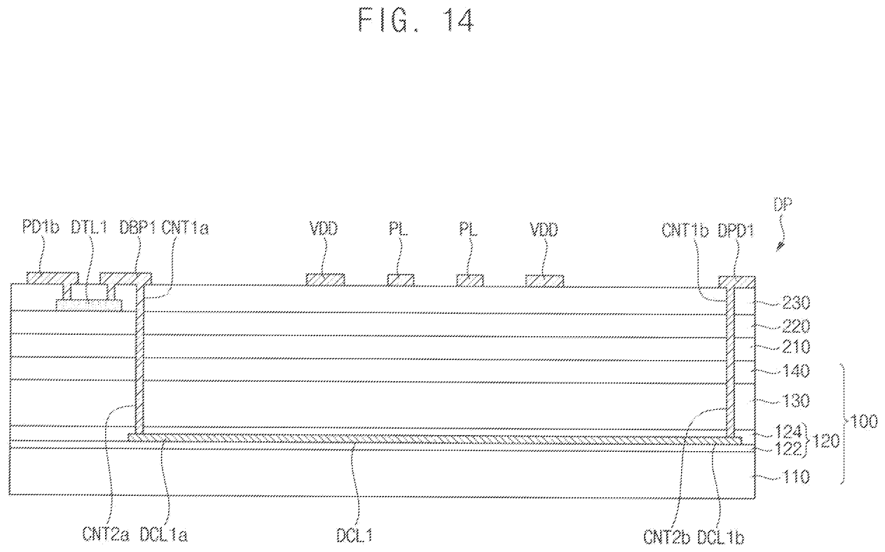

Subsequently, a plurality of contact holes may be formed in the insulating layers. According to some embodiments, the contact holes overlapping the first data transmission line DTL1 of FIG. 14 may be substantially simultaneously formed with the contact holes overlapping the active layer ACT of FIG. 4. In addition, upper contact holes CNT1a and CNT1b formed in the first and second insulating layers 220 and 230 among the contact holes overlapping the first data connection line DCL1 of FIG. 14 may be substantially simultaneously formed with the contact holes overlapping the active layer ACT of FIG. 4. Lower contact holes CNT2a and CNT2b formed in the first upper barrier layer 124, the second resin layer 130, the second barrier layer 140, and the buffer layer 210 among the contact holes overlapping the first data connection line DCL1 of FIG. 14 may be formed after the upper contact holes CNT1a and CNT1b are formed. For example, the lower contact holes CNT2a and CNT2b may be formed through a different photolithography process and an etching process using a different mask from the upper contact holes CNT1a and CNT1b. The description of the contact holes may be substantially equally applied to contact holes overlapping other lines.

The source electrode SE, the drain electrode DE, the first and second data lines DL1 and DL2, and the power lines PL may be formed in the display area DA on the second insulating layer 230.

The second portions DFL1b and DFL2b of the first and second data fan-out lines DFL1 and DFL2, the driving voltage line VDD, the first gate control line GCTL1, the second portion GTL1b of the first gate transmission line GTL1, the second portions PTL1b and PTL2b of the first and second power transmission lines PTL1 and PTL2, the first-first pads PD1a, the first-second pads PD1b, the second-first pads PD2a, the second-second pads PD2b, the first data bridge patterns DBP1, the first gate bridge pattern GBP1, the first power bridge pattern PBP1, the first and second data pads DPD1 and DPD2, the first and second power pads PPD1 and PPD2, and the first gate pad GPD1 may be formed in the non-display area NDA on the second insulating layer 230.

For example, a conductive material layer may be entirely formed in the display area DA and the non-display area NDA on the second insulating layer 230. Subsequently, the source electrode SE, the drain electrode DE, the first and second data lines DL1 and DL2, the power lines PL, the second portions DFL1b and DFL2b of the first and second data fan-out lines DFL1 and DFL2, the driving voltage line VDD, the first gate control line GCTL1, the second portion GTL1b of the first gate transmission line GTL1, the second portions PTL1b and PTL2b of the first and second power transmission lines PTL1 and PTL2, the first-first pads PD1a, the first-second pads PD1b, the second-first pads PD2a, the second-second pads PD2b, the first data bridge patterns DBP1, the first gate bridge pattern GBP1, the first power bridge pattern PBP1, the first and second data pads DPD1 and DPD2, the first and second power pads PPD1 and PPD2, and the first gate pad GPD1 may be substantially simultaneously formed by patterning the conductive material layer.

Referring to FIGS. 2, 4 and 15, the third insulating layer 240, the light emitting element LED, the fourth insulating layer 250, and the encapsulation layer 300 may be formed on the second insulating layer 230. Accordingly, the display panel DP may be manufactured.

Subsequently, the first gate driver GDV1, the first data driving chip DIC1, and the second data driving chip DIC2 may be located in the non-display area NDA of the display panel DP. In addition, the first notch NT1 may be formed in the non-display area NDA of the display panel DP. For example, the first notch NT1 may be formed by laser drilling.

According to some embodiments, the first notch NT1 may be formed after the first gate driver GDV1, the first data driving chip DIC1, and the second data driving chip DIC2 are located in the non-display area NDA of the display panel DP. According to some embodiments, the first notch NT1 may be formed before the first gate driver GDV1, the first data driving chip DIC1, and the second data driving chip DIC2 are located in the non-display area NDA of the display panel DP.

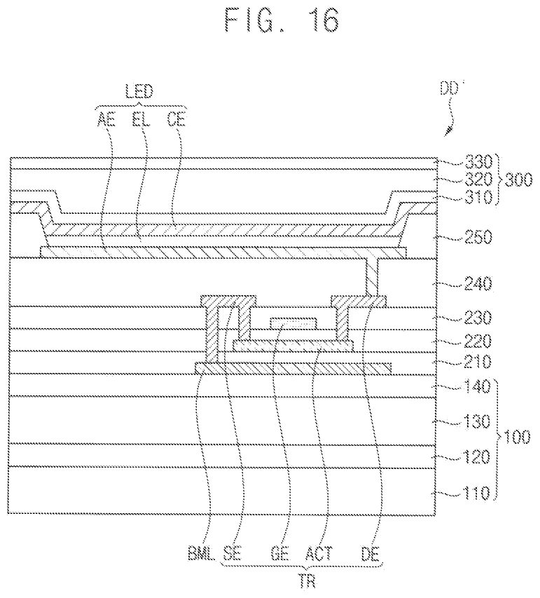

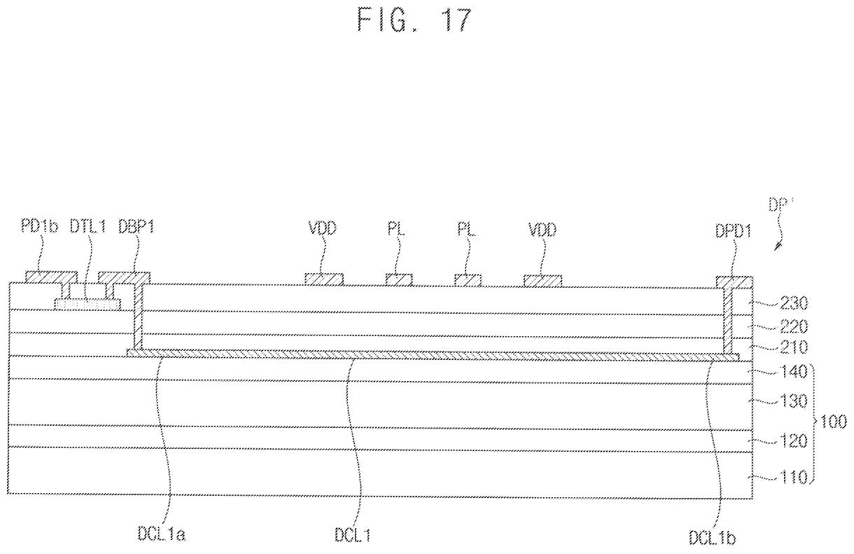

FIGS. 16 and 17 are cross-sectional views illustrating a display device according to some embodiments. FIG. 16 may correspond to FIG. 4, and FIG. 17 may correspond to FIG. 6. Hereinafter, differences from the embodiments described with reference to FIGS. 1 to 8 will be mainly described.

Referring to FIGS. 16 and 17, a display device DD′ (or a display panel DP′ included in the display device DD′) may further include a lower metal layer BML located between the second barrier layer 140 and the buffer layer 210. The lower metal layer BML may include a conductive material.

The lower metal layer BML may block light incident on the active layer ACT through the substrate 100 to prevent or reduce deterioration of electrical properties of the active layer ACT.

According to some embodiments, the lower metal layer BML may be electrically connected to the source electrode SE, and a constant voltage may be applied to the lower metal layer BML. According to some embodiments, the lower metal layer BML may be used as lines such as the power lines PL, the gate lines GL, the data lines DL, or the like.

The first data connection line DCL1 may be located on the same layer as the lower metal layer BML. That is, the first data connection line DCL1 may be located between the second barrier layer 140 and the buffer layer 210. The first gate connection line GCL1 and the first power connection line PCL1 may be located on the same layer as the first data connection line DCL1. For example, the first barrier layer 120 may have a single-layered structure.

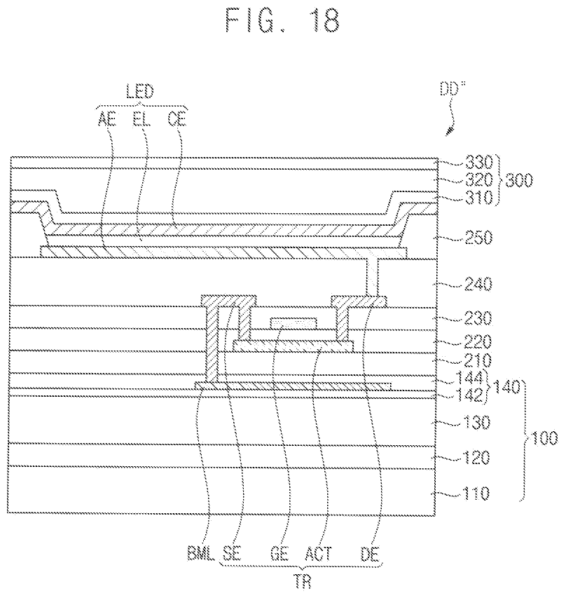

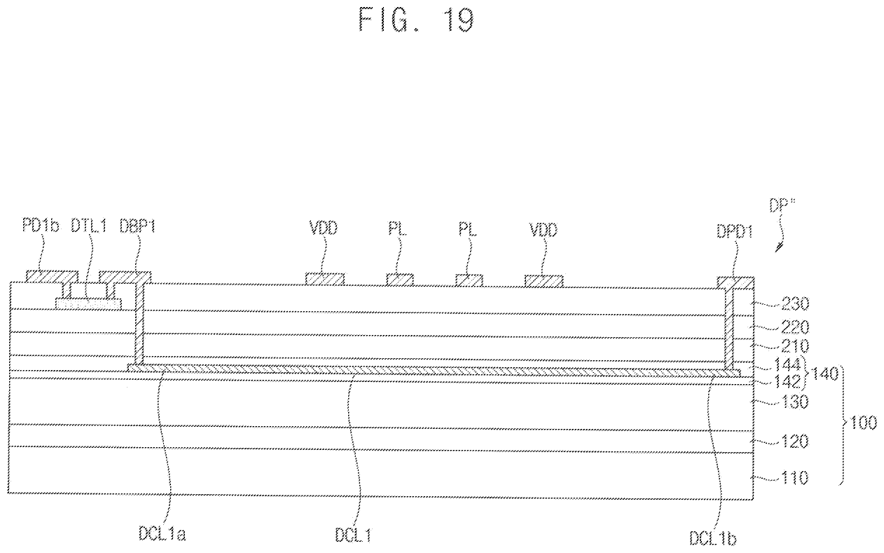

FIGS. 18 and 19 are cross-sectional views illustrating a display device according to some embodiments. FIG. 18 may correspond to FIG. 4, and FIG. 19 may correspond to FIG. 6. Hereinafter, differences from the embodiments described with reference to FIGS. 16 and 17 will be mainly described.

Referring to FIGS. 18 and 19, the second barrier layer 140 may include a second lower barrier layer 142 and a second upper barrier layer 144. The second upper barrier layer 144 may be located between the second lower barrier layer 142 and the buffer layer 210. A thickness of the second lower barrier layer 142 may be less than a thickness of the second upper barrier layer 144.

The lower metal layer BML may be located between the second lower barrier layer 142 and the second upper barrier layer 144.

The first data connection line DCL1 may be located on the same layer as the lower metal layer BML. That is, the first data connection line DCL1 may be located between the second lower barrier layer 142 and the second upper barrier layer 144. The first gate connection line GCL1 and the first power connection line PCL1 may be located on the same layer as the first data connection line DCL1.

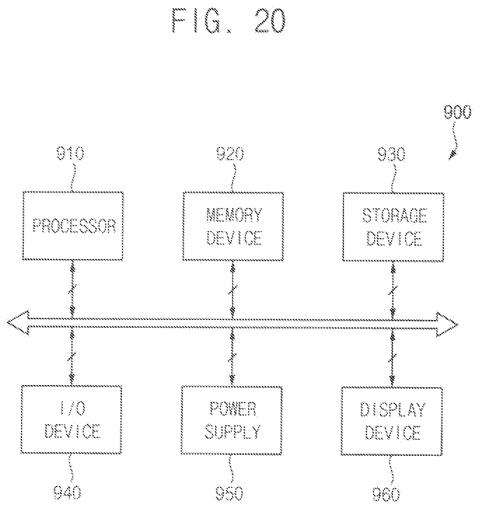

FIG. 20 is a block diagram illustrating an electronic device according to some embodiments.

Referring to FIG. 20, according to some embodiments, an electronic device 900 may include a processor 910, a memory device 920, a storage device 930, an input/output (“I/O”) device 940, a power supply 950, and a display device 960. Here, the display device 960 may correspond to the display device DD of FIGS. 1 to 8, the display device DD′ of FIGS. 16 and 17, or the display device DD″ of FIGS. 18 and 19. The electronic device 900 may further include a plurality of ports for communicating with a video card, a sound card, a memory card, a universal serial bus (“USB”) device, or the like. According to some embodiments, the electronic device 900 may be implemented as a television. According to some embodiments, the electronic device 900 may be implemented as a smart phone. However, embodiments are not limited thereto, according to some embodiments, the electronic device 900 may be implemented as a cellular phone, a video phone, a smart pad, a smart watch, a tablet personal computer (“PC”), a car navigation system, a computer monitor, a laptop, a head secured or located (e.g., mounted) display (“HMD”), or the like.

The processor 910 may perform various computing functions. According to some embodiments, the processor 910 may be a microprocessor, a central processing unit (“CPU”), an application processor (“AP”), or the like. The processor 910 may be coupled to other components via an address bus, a control bus, a data bus, or the like. According to some embodiments, the processor 910 may be coupled to an extended bus such as a peripheral component interconnection (“PCI”) bus.

The memory device 920 may store data for operations of the electronic device 900. According to some embodiments, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

According to some embodiments, the storage device 930 may include a solid state drive (“SSD”) device, a hard disk drive (“HDD”) device, a CD-ROM device, or the like. According to some embodiments, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. According to some embodiments, the display device 960 may be included in the I/O device 940.

Although certain embodiments and implementations have been described herein, other embodiments and modifications will be apparent from this description. Accordingly, the disclosures are not limited to such embodiments, and some embodiments are further defined in the appended claims, and their equivalents.

What is claimed is:

1. A display device comprising:
a display panel having a first non-folding portion, a first folding portion, a second non-folding portion, a second folding portion, and a third non-folding portion arranged along a first direction, wherein each of the first to third non-folding portions has a display area, a bending area extending along a second direction crossing the first direction, and a pad area connected to the display area with the bending area interposed therebetween;
a first data driving chip on a first pad area of the first non-folding portion;
a second data driving chip on a second pad area of the second non-folding portion;
a third data driving chip on a third pad area of the third non-folding portion; and
a circuit board attached on any one of the first to third pad areas and electrically connected to the first to third data driving chips.

2. The display device of claim 1, wherein
the first folding portion configured to be folded about a first folding axis extending in the second direction, and
the second folding portion configured to be folded about a second folding axis spaced apart from the first folding axis in the first direction and extending in the second direction.

3. The display device of claim 2, further comprising:
a first notch overlapping the first folding axis and concave inward that is between the first pad area and the second pad area of the display panel; and
a second notch overlapping the second folding axis and concave inward that is between the second pad area and the third pad area of the display panel.

4. The display device of claim 3, wherein
in each of the first to third non-folding portions, the bending area is bent about a bending axis extending in the first direction such that the pad area is under the display area, and
each of the first notch and the second notch overlaps the bending axis.

5. The display device of claim 3, wherein the circuit board is attached on the second pad area of the second non-folding portion and spaced apart from the second data driving chip.

6. The display device of claim 5, wherein the display panel includes a first data connection line including a first end portion in the first pad area and a second end portion in the second pad area, and electrically connecting the first data driving chip and the circuit board.

7. The display device of claim 6, wherein the first data connection line overlaps the first non-folding portion, the first folding portion, and the second non-folding portion.

8. The display device of claim 6, wherein the first data connection line extends to surround the first notch.

9. The display device of claim 6, wherein the display panel further includes:
a first resin layer;
a first barrier layer on the first resin layer;
a second resin layer on the first barrier layer;
a second barrier layer on the second resin layer;
a buffer layer on the second barrier layer;
a thin film transistor on the buffer layer; and
a light emitting element electrically connected to the thin film transistor.

10. The display device of claim 9, wherein
the first barrier layer includes a first lower barrier layer on the first resin layer and a first upper barrier layer between the first lower barrier layer and the second resin layer, and
the first data connection line is between the first lower barrier layer and the first upper barrier layer.

11. The display device of claim 9, wherein
the second barrier layer includes a second lower barrier layer on the second resin layer and a second upper barrier layer between the second lower barrier layer and the buffer layer, and
the first data connection line is between the second lower barrier layer and the second upper barrier layer.

12. The display device of claim 9, wherein the first data connection line is between the second barrier layer and the buffer layer.

13. The display device of claim 6, wherein the display panel further includes a second data connection line including a first end portion positioned in the third pad area and a second end portion positioned in the second pad area, and electrically connecting the third data driving chip and the circuit board.

14. The display device of claim 13, wherein the second data connection line extends to surround the second notch.

15. The display device of claim 6, wherein
the display panel further includes a data transmission line in the second pad area and electrically connecting the second data driving chip and the circuit board, and
the data transmission line is on a different layer from the first data connection line.

16. The display device of claim 6, further comprising a gate driver on the first non-folding portion, and
wherein the display panel further includes a gate connection line including a first end portion in the first pad area and a second end portion in the second pad area, and electrically connecting the gate driver and the circuit board.

17. The display device of claim 16, wherein the gate connection line is on a same layer as the first data connection line.

18. The display device of claim 6, wherein the display panel further includes:
a driving voltage line extending in the first direction and partially overlapping the first non-folding portion; and
a power connection line including a first end portion positioned in the first pad area and a second end portion positioned in the second pad area, and electrically connecting the driving voltage line and the circuit board.

19. The display device of claim 18, wherein the power connection line is on a same layer as the first data connection line.

20. A display device comprising:
a display panel having a first non-folding portion, a first folding portion, a second non-folding portion, a second folding portion, and a third non-folding portion arranged along a first direction, wherein each of the first to third non-folding portions has a display area, a bending area extending along a second direction crossing the first direction from the display area, and a pad area connected to the display area with the bending area interposed therebetween;
a first data driving chip on a first pad area of the first non-folding portion;
a second data driving chip on a second pad area of the second non-folding portion;
a third data driving chip on a third pad area of the third non-folding portion; and
a circuit board attached on the second pad area of the second non-folding portion to be spaced apart from the second data driving chip, and electrically connected to the first to third data driving chips, and
wherein the display panel includes:
a first data connection line including a first end portion in the first pad area and a second end portion in the second pad area, and electrically connecting the first data driving chip and the circuit board; and
a second data connection line including a first end portion positioned in the third pad area and a second end portion in the second pad area, and electrically connecting the third data driving chip and the circuit board.
